(19) United States
(12) Patent Application Publication
(10) Pub. No.: US 2019/0011758 A1
(43) Pub. Date: Jan. 10, 2019

(54) DISPLAY DEVICE

(71) Applicant: Samsung Display Co., Ltd., Yongin-si (KR)

(72) Inventors: Sang-Gil Lee, Seoul (KR); Byung-Gon Kum, Suwon-si (KR); Eun Guk Lee, Seoul (KR)

(21) Appl. No.: 15/845,135

(22) Filed: Dec. 18, 2017

(30) Foreign Application Priority Data
Jul. 7, 2017 (KR) 10-2017-0086699

(51) Int. Cl. G02F 1/1333; H05B 33/10; H05B 33/14; H01L 51/00; H01L 51/50; H01L 51/56; G02F 1/1335; G02F 1/1343; H01L 33/26; H01L 27/32

(52) U.S. Cl. CPC G02F 1/133305; H05B 33/10; H05B 33/14; H01L 51/0013; H01L 51/0015; H01L 27/322; H01L 51/56; G02F 1/133603; G02F 1/1343; H01L 33/26; H01L 27/3211; H01L 51/502

(57) ABSTRACT

A display device includes: a lower panel through which incident light passes and including a substrate on which a thin film transistor is disposed; a color conversion display panel from which converted light is emitted to display an image and overlapping the lower panel; and a polarization film between the lower panel and the color conversion display panel. The color conversion display panel includes a substrate on which are disposed: a first color conversion layer including first semiconductor nanocrystals which convert the incident light to the converted light; a second color conversion layer including second semiconductor nanocrystals which convert the incident light to the converted light; and a transmission layer through which unconverted incident light passes. The substrate of the lower panel or the color conversion display panel includes a flexible substrate including a polymer.

This application claims priority to Korean Patent Application No. 10-2017-0086699 filed on Jul. 7, 2017, and all the benefits accruing therefrom under 35 U.S.C. § 119, the content of which in its entirety is incorporated herein by reference.

### BACKGROUND

### (a) Field

The present disclosure relates to a display device.

### (b) Description of the Related Art

A liquid crystal display device used as a display device may include two field generating electrodes, a liquid crystal layer, a color filter and a polarization layer. Light generated from a light source may pass through the liquid crystal layer, the color filter and the polarization layer and thus reach a viewer. However, light loss may occur in the polarization layer and the color filter. Light loss may occur not only in the liquid crystal display device, but also in an organic light emitting display device using a color filter.

In order to implement a display device that can reduce light loss in a polarization layer and increase color reproducibility, a display device that includes a color conversion display panel using semiconductor nanocrystals such as quantum dots has been suggested.

A curved or flexible liquid crystal display has been developed to increase the immersion of a viewer in the liquid crystal display.

### SUMMARY

The invention has been made in an effort to provide a curved display device having excellent color reproducibility.

A display device according to an exemplary embodiment includes: a lower panel through which incident light passes, the lower panel including a substrate on which a thin film transistor is disposed; a color conversion display panel from which converted light is emitted to display an image, the color conversion display panel overlapping the lower panel; and a polarization film disposed between the lower panel and the color conversion display panel. The color conversion display panel includes a substrate on which are disposed: a first color conversion layer including first semiconductor nanocrystals which convert the incident light to the converted light; a second color conversion layer including second semiconductor nanocrystals which convert the incident light to the converted light; and a transmission layer through which unconverted incident light passes. The substrate of the lower panel or the substrate of the color conversion display panel includes a flexible substrate including a polymer.

The display device may further include an upper panel through which the incident light passed through the lower panel passes to the color conversion display panel. With the substrate of the lower panel or the substrate of the color conversion display panel including the flexible substrate including the polymer, the upper panel may include a flexible substrate including a polymer.

The polarization film may be disposed between the upper panel and the color conversion display panel.

The display device may further include an adhesion layer disposed between the polarization film and the upper panel and between the polarization film and the color conversion display panel.

The adhesion layer may include at least one of a pressure sensitive adhesive (“PSA”), an optically clear adhesive (“OCA”) and an optically clear resin (“OCR”).

The flexible substrate including the polymer may include at least one of an acryl resin, a polycarbonate and a cycloolefin polymer (“COP”).

The display device may further include: a light unit which generates blue light as the incident light and emits the incident blue light to the lower panel; and a first polarization layer disposed between the lower panel and the light unit and into which the incident blue light is incident to the display device.

The substrate of the lower panel, the substrate of the color conversion display panel and the flexible substrate of the upper panel each may have a thickness of about 1 micrometer (μm) to about 10 micrometers (μm).

The display device may further include an anti-reflection film disposed on the upper panel and through which the converted light exits the display device to display the image.

The display device may be curved.

A display device according to an exemplary embodiment includes: a lower panel through which incident passes, the lower panel including a thin film transistor; a color conversion display panel from which converted light is emitted to display an image, the color conversion display panel overlapping the lower panel; a light unit which generates blue light as the incident light and emits the incident blue light to the lower panel; a first polarization layer disposed between the lower panel and the light unit; a polarization film disposed on the color conversion display panel to face the lower panel; and an adhesion layer disposed between the polarization film and the color conversion display panel. The color conversion display panel includes: a first color conversion layer including first semiconductor nanocrystals which convert the incident light to the converted light; a second color conversion layer including second semiconductor nanocrystals which convert the incident light to the converted light; and a transmission layer through which unconverted incident light passes.

According to one or more of the exemplary embodiments, color reproducibility of the display device can be improved. In addition, since the display device is provided as a curved display device, the immersion of a viewer can be increased.

### BRIEF DESCRIPTION OF THE DRAWINGS

The above and other advantages and features of this disclosure will become more apparent by describing in further detail exemplary embodiments thereof with reference to the accompanying drawings, in which:

FIG. 1 is a top plan view of an exemplary embodiment of pixels of a display device according to the invention.

FIG. 2 is a cross-sectional view of FIG. 1, taken along line

FIG. 3, FIG. 4, FIG. 5, FIG. 6 and FIG. 7 are cross-sectional views of an exemplary embodiment of a manufacturing process of a display device according to the invention.

### DETAILED DESCRIPTION

Hereinafter, exemplary embodiments of the invention will be described in more detail with reference to the accompanying drawings. As those skilled in the art would realize, the described embodiments may be modified in various different ways, all without departing from the spirit or scope of the invention.

The drawings and description are to be regarded as illustrative in nature and not restrictive. Like reference numerals designate like elements throughout the specification.

In addition, the size and thickness of each configuration shown in the drawings to are arbitrarily shown for better understanding and ease of description, but the invention is not limited thereto. In the drawings, the thickness of layers, films, panels, regions, etc., are exaggerated for clarity.

It will be understood that when an element such as a layer, film, region, or substrate is referred to as being related to another element such as being “on” another element, it can be directly on the other element or intervening elements may also be present. In contrast, when an element is referred to as being related to another element such as being “directly on” another element, there are no intervening elements present. Further, throughout the specification, the word “on” means positioning on or below the object portion, but does not essentially mean positioning on the upper side of the object portion based on a gravitational direction.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “At least one” is not to be construed as limiting “a” or “an.” “Or” means “and/or.” As used herein, the term “and/or” includes any and all combinations of one or more of the associated listed items. In addition, unless explicitly described to the contrary, the word “comprise” and variations such as “comprises” or “comprising” will be understood to imply the inclusion of stated elements but not the exclusion of any other elements.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within±30%, 20%, 10% or 5% of the stated value.

In addition, in this specification, the phrase “on a plane” means viewing a target portion from the top, and the phrase “on a cross-section” means viewing a cross-section formed by vertically cutting a target portion from the side.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

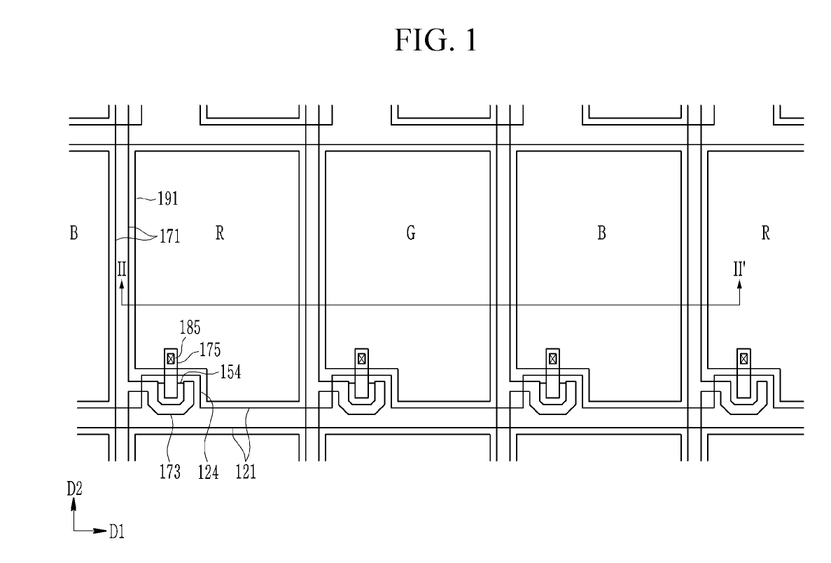

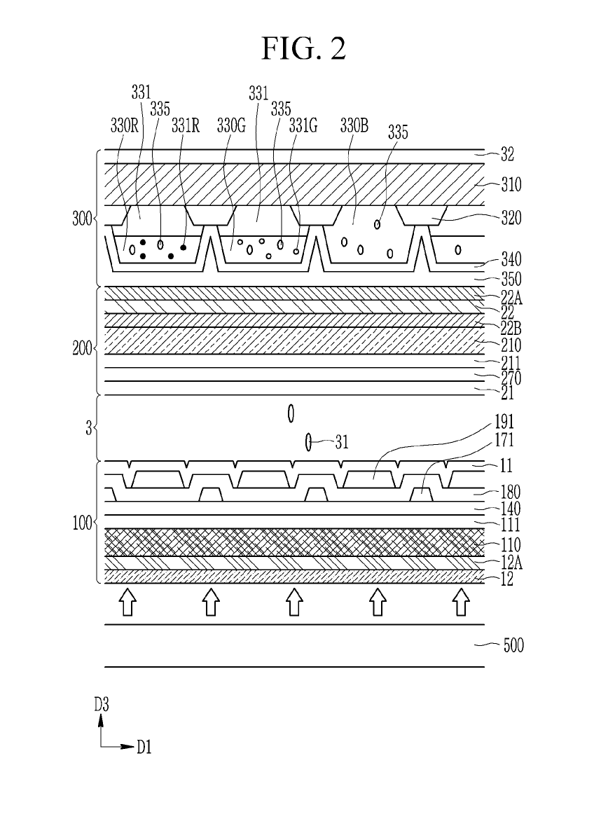

Hereinafter, an exemplary embodiment of a display device according to the invention will be described with reference to FIG. 1 and FIG. 2. FIG. 1 is a top plan view of an exemplary embodiment of pixels in a display device according to the invention, and FIG. 2 is a cross-sectional view of FIG. 1, taken along line The display device and component layers thereof are disposed in a plane defined by first and second directions D1 and D2 crossing each other. A thickness of the display device and component layers thereof is defined in a third direction D3 crossing each of the first and second directions D1 and D2. The first through third directions D1, D2 and D3 may be perpendicular to each other, but are not limited thereto.

Referring to FIG. 1 and FIG. 2, an exemplary embodiment of a display device according to the invention includes a light unit 500, a lower (display) panel 100 including a switching element such as a thin film transistor, an upper (display) panel 200 and a color conversion display panel 300 that overlap the lower panel 100, and an optical control (or transmittance) layer such as a liquid crystal layer 3 that is disposed between the lower panel 100 and the upper panel 200. The display device displays an image with light. The upper and lower panels 200 and 100 may be collectively referred to as a display panel. Pixels are controlled or driven within the display panel, to control light transmittance therethrough to generate an image displayed by the display device.

The display device may include a display area at which the image is displayed with light, and a non-display area at which the image is not displayed. The pixels of the display device are disposed in the display area. Although not shown in the drawings, a sealing region at which the upper and lower panels 200 and 100 are bonded to each other may be disposed in the non-display area of the display device.

The light unit 500 may include a light source that is disposed at a bottom side of the lower panel 100 and generates light, and a light guide (not shown) that receives the light from the light source and guides the received light toward the lower panel 100. As indicated by the upward arrows in FIG. 2, the guided light is emitted from the light unit 500 and provided to an incident surface (e.g., a lower surface) of the lower panel 100. The light unit 500 according to the exemplary embodiment may be flexible so as to be curved, but not being limited thereto.

The light unit 500 may include any light source that emits blue light, and for example, may include a light emitting diode. The light source may be an edge type light source that is disposed on at a side surface of the display device or a direct-under type light source disposed directly under the light guide (not shown) and the display panel 100, but this is not restrictive. Instead of the light unit 500 including the blue light source, a light unit 500 including a white light source or an ultraviolet (“UV”) light source may be used. However, for purpose of explanation, the display device according to the exemplary embodiment includes the light unit 500 including the blue light source.

The lower panel 100 including a switching element such as a thin film transistor is disposed between the liquid crystal layer 3 and the light unit 500.

The lower panel 100 includes a first polarization layer 12 that is disposed between a first (base) substrate 110 and the light unit 500. The first polarization layer 12 polarizes light incident from the light unit 500. While it is described that the lower panel 100 includes the first polarization layer 12, it is understood that the first polarization layer 12 as an element of a display device may be considered disposed on the lower panel 100.

The first polarization layer 12 may be disposed at one side (e.g., a lower side) of the first substrate 110 using various methods of manufacturing the first polarization layer 12. As reflecting methods of manufacturing, the first polarization layer 12 may be one of an application-type polarization layer which is applied to the first substrate 100, a coating-type polarization layer which is coated on the first substrate 110, a film-type polarization layer and a wire grid polarizer, and may be.

The first polarization layer 12 may be combined with the first substrate 110 through an adhesion layer 12A according to the exemplary embodiment. The adhesion layer 12A may include be made of any material that can combine the first polarization layer 12 and the first substrate 110 to each other. In an exemplary embodiment, for example, the adhesion layer 12A may include a pressure sensitive adhesive (“PSA”), an optically clear adhesive (“OCA”), an optically clear resin (“OCR”), an air gap, beads, and the like. A first polarization member may collectively include the first polarization layer 12 and the adhesion layer 12A.

Referring to FIG. 1, within the lower panel 100, the first substrate 110 includes a pixel provided in plurality disposed in a matrix format. Transmittance of the light from the light unit 500 may be controlled at the pixels, such that light is emitted or blocked at the pixels to display an image. The first substrate 110 is a flexible substrate having flexibility, and may include a polymer. The polymer may include at least one of an acryl-based resin, a polycarbonate, a cycloolefin polymer (“COP”), a polyimide resin, and a polyamide resin, but this is not restrictive. The polymer may include any material having a relatively low phase difference value.

In an exemplary embodiment, for example, the first substrate 110 including an acryl-based resin may include a resin including or manufactured from an acryl-based monomer. The acryl-based monomer may include a vinyl group (CH₂═CH) and an ester group (—CO—O—). Particularly, the ester group may be combined with any one of the two carbons of the vinyl group linked by a double bond.

The first substrate 110 may have a thickness of about 1 micrometer (μm) to about 10 micrometers (μm). In an exemplary embodiment, the thickness of the first substrate 110 may be, for example, 2 μm to 4 μm. The thicknesses of the first substrate 110 may be a maximum thickness of the first substrate 110. In addition, adhesion strength of the first substrate 110 may be about 1 gram force per inch (gf/in).

A first buffer layer 111 may be disposed on the first substrate 110. The first buffer layer 111 may include an inorganic material, and may include, for example, at least one of a silicon oxide, a silicon nitride, and a silicon nitroxide. In exemplary embodiments, the first buffer layer 111 may be omitted.

The first buffer layer 111 may have a thickness of about 500 angstroms (Å) to about 1500 Å, and may be, for example, 800 Å to 1200 Å in thickness. The thickness of the first buffer layer 111 described above may be a maximum thickness thereof.

The lower panel 100 may include a gate line 121 disposed on the first buffer layer 111, having a length thereof extending in the first direction D1, and including or defining a gate electrode 124, a gate insulation layer 140 disposed between the gate line 121 and the liquid crystal layer 3, a semiconductor layer 154 disposed between the gate insulation layer 140 and the liquid crystal layer 3, a data line 171 disposed between the semiconductor layer 154 and the liquid crystal layer 3 and having a length thereof extending in a second direction D2, a source electrode 173 connected to the data line 171, a drain electrode 175 disposed apart from the source electrode 173, and a passivation layer 180 disposed between the data line 171 and the liquid crystal layer 3.

Any of the aforementioned elements of the lower panel 100 may be provided in plurality on the first substrate 110 and within the display device.

The semiconductor layer 154 forms a channel layer in a portion of the semiconductor layer 154 that is not covered by the source electrode 173 and the drain electrode 175. The channel layer of the semiconductor layer 154 may define a channel of the thin film transistor. The gate electrode 124, the semiconductor layer 154, the source electrode 173 and the drain electrode 175 may together form one thin film transistor.

A pixel electrode 191 is disposed on the passivation layer 180. The pixel electrode 191 may be physically and electrically connected with the thin film transistor, such as at the drain electrode 175, through or at a contact hole 185 provided in the passivation layer 180. The thin film transistor connected to the pixel electrode 191 controls or drives the pixel in which the pixel electrode 191 is disposed, to form an image with light.

A first alignment layer 11 may be disposed between the pixel electrode 191 and the liquid crystal layer 3.

The upper panel 200 includes a second (base) substrate 210. The second substrate 210 may be a flexible substrate having flexibility, and may include a polymer. The polymer may, for example, include at least one of an acryl-based resin, a polycarbonate, and a cycloolefin polymer (“COP”), but this is not restrictive. The polymer may include any material having a relatively low phase difference value.

In an exemplary embodiment, for example, the second substrate 210 including an acryl-based resin may include a resin manufactured from an acryl-based monomer. The acryl-based monomer may include a vinyl group (CH₂═CH) and an ester group (—CO—O). Particularly, the ester group may be combined with any one of the two carbons of the vinyl group linked by a double bond.

The second substrate 210 may have a thickness of about 1 μm to about 10 μm, and the thickness may be, for example, 2 μm to 4 μm. The thicknesses of the second substrate 210 may be a maximum thickness of the second substrate 210. In addition, adhesion strength of the second substrate 210 may be about 1 gf/in.

A second buffer layer 211, a common electrode 270, and a second alignment layer 21 may be sequentially disposed between the second substrate 210 and the liquid crystal layer 3.

The second buffer layer 211 may include an inorganic material, and for example, may include at least one of a silicon oxide, a silicon nitride, and a silicon nitroxide. In exemplary embodiments, the second buffer layer 211 may be omitted.

The second buffer layer 211 may have a thickness of about 500 Å to about 1500 Å, and may be, for example, 800 Å to 1200 Å thick. The thickness of the second buffer layer 211 described above may be a maximum thickness thereof.

The common electrode 270 forms an electric field with the pixel electrode 191. In the present exemplary embodiment, the common electrode 270 is included in the upper panel 200, but this is not restrictive. The common electrode 270 may be disposed in the lower panel 100.

The second buffer layer 211 may be disposed at a first side of the second substrate 210, facing the liquid crystal layer 3, and a second polarization layer 22 may be disposed at a second side of the second substrate 210 opposite to the first side thereof, facing the color conversion display panel 300. An adhesion layer 22B may be disposed between the second side of the second substrate 210 and the second polarization layer 22. For convenience of description, the upper panel 200 may be considered as including the second polarization layer 22 or the second polarization layer 22 as an element of a display device may be considered disposed on the upper panel 200.

The adhesion layer 22B may include or be made of any material that can combine the second polarization layer 22 and the second substrate 210 to each other. In an exemplary embodiment, for example, may include a pressure sensitive adhesive (“PSA”), an optically clear adhesive (“OCA”), an optically clear resin (“OCR”), an air gap, beads, and the like.

The second polarization layer 22 may be provided as a film-type polarization layer to have a relatively small thickness, and may have flexibility.

The liquid crystal layer 3 is disposed between the lower panel 100 and the upper panel 200, and includes a plurality of liquid crystal molecules 31. Orientation and movement of the liquid crystal molecules 31 is controlled by the electric field formed between the pixel electrode 191 and the common electrode 270. An image can be displayed by the display device by controlling transmittance of light received from the light unit 500 according to the degree of movement of the liquid crystal molecules 31.

In an exemplary embodiment, a color conversion display panel 300 may be disposed on and facing the second side of the second substrate 210.

The color conversion display panel 300 includes a third (base) substrate 310 that has flexibility and includes a polymer. The polymer may, for example, include at least one of an acryl-based resin, a polycarbonate, and a cycloolefin polymer (“COP”), but this is not restrictive. The polymer may include any material having a relatively low phase difference value.

In an exemplary embodiment, for example, the third substrate 310 including an acryl-based resin may include a resin manufactured from an acryl-based monomer. The acryl-based monomer may include a vinyl group (CH₂═CH) and an ester group (—CO—O—). Particularly, the ester group may be combined with any one of the two carbons of the vinyl group linked by a double bond.

The third substrate 310 may have a thickness of about 1 μm to about 10 μm, and may be for example, 2 μm to 4 μm thick. The thicknesses of the third substrate 310 may be a maximum thickness of the third substrate 310. In addition, adhesion strength of the third substrate 310 may be about 1 gf/in.

Light emitted from the light unit 500 passes through layers of the display device and thus reaches a viewer at a view side of the display device (e.g., upper side in FIG. 2). An anti-reflection film 32 may be disposed at one side of the third substrate 310 that is closest to the viewer. The anti-reflection film 32 reduces or effectively prevents reflection of external light by absorbing the external light, and reduces or effectively prevents distortion of a color light emitted from the display device. Converted light may exit the display device through the anti-reflection film 32 to display an image at a viewing side of the display device.

A light blocking member 320 having a lattice shape in the top plan view may be provided at one side of the third substrate 310 which faces the upper panel 200. Referring to FIG. 1 and FIG. 2, portions of the light blocking member 320 respectively correspond to the data lines 171, such as being extended along the lengths thereof. Although not shown, to form the lattice shape, portions of the light blocking member 320 may also correspond to the gate lines 121, such as being extended along the lengths thereof. In the present exemplary embodiment, the light blocking member 320 contacts the third substrate 310, but this is not restrictive. A buffer layer (not shown) may be provided between the third substrate 310 and the light blocking member 320.

A blue light cutting filter 331 is disposed between the third substrate 310 and the upper panel 200. The blue light cutting filter 331 is disposed to be overlapped with areas of the display device that emit red and green light, and is not disposed in an area of the display device that emits blue light. Referring to FIG. 1 and FIG. 2, portions of the blue light cutting filter 331 are provided at both a red pixel area (B) and a green pixel area (G), but are not provided at the blue pixel area (B). The portions of the blue light cutting filter are each labeled as 331 in FIG. 2 for convenience of description.

The blue light cutting filter 331 includes a first (portion) area that overlaps a first color conversion layer 330R and a second (portion) area that overlaps a second color conversion layer 330G. The areas or portions of the blue light cutting filter 331 may be disposed spaced apart from each other. While the portions of the blue light cutting filter 331 are shown spaced apart from each other in the first direction D1 in FIG. 2, these portions may also be spaced apart from each other in the second direction. However, this is not restrictive, and the first area and the second area of the blue light cutting filter 331 may be connected with each other in the first direction D1 and/or the second direction D2.

The blue light cutting filter 331 may block or absorb blue light supplied from the light unit 500 to be incident on the color conversion display panel 300. The blue light incident on the first color conversion layer 330R and the second color conversion layer 330G from the light unit 500 is converted into red or green light, respectively, by semiconductor nanocrystals 331R and 331G. As some of the blue light may be emitted from the first color conversion layer 330R and the second color conversion layer 330G without color conversion, such blue light and the red light or the green light are mixed, thereby causing deterioration of color reproducibility. In one or more exemplary embodiment, the blue light cutting filter 331 disposed in a light-emitting path of the first color conversion layer 330R and the second color conversion layer 330G absorbs blue light emitted from the first color conversion layer 330R and the second color conversion layer 330G without being color converted, to thereby reduce or effectively prevent the red light or the green light from being mixed with the blue light.

The blue light cutting filter 331 may include any material for carrying out the above-stated effect, and may include, for example, a yellow color filter. The blue light cutting filter 331 may have a structure of a single layer or a laminated structure of multiple layers along a thickness direction thereof.

The plurality of color conversion layers 330R and 330G are respectively disposed between portions of the blue light cutting filter 331, and the upper panel 200. A transmission layer 330B may be disposed between the third substrate 310 and the upper panel 200.

The plurality of color conversion layers 330R and 330G may convert incident light into light having a wavelength that is different from that of the incident light, and emit the wavelength-converted light to outside the respective color conversion layer. The plurality of color conversion layers 330R and 330G may include the first color conversion layer 330R and the second color conversion layer 330G, and the first color conversion layer 330R may be a red color conversion layer and the second color conversion layer 330G may be a green color conversion layer.

The transmission layer 330B does not color-convert and/or wavelength-convert light incident thereto. In an exemplary embodiment, for example, blue light may be incident to the transmission layer 330B and thus the unconverted blue light may be emitted therefrom. In this case, the blue light incident to the transmission layer 330B may be scattered by a scatterer 335 therein, and then emitted as scattered light.

The first color conversion layer 330R may include first semiconductor nanocrystals 331R that convert blue light into red light. The first semiconductor nanocrystals 331R may include at least one of a phosphor and a quantum dot.

The second color conversion layer 330G may include second semiconductor nanocrystals 331G that convert incident blue light into green light. The second semiconductor nanocrystals 331G may include at least one of a phosphor and a quantum dot.

The quantum dot may be selected from a group II-VI compound, a group III-V compound, a group IV-VI compound, a group IV element, a group IV compound and a combination thereof.

The II-VI group compound may be selected from: a group of two-element compounds selected from CdSe, CdTe, ZnS, ZnSe, ZnTe, ZnO, HgS, HgSe, HgTe, MgSe, MgS, and a combination thereof; a group of three-element compounds selected from CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a combination thereof; and a group of four-element compounds selected from HgZnTeS, CdZnSeS, CdZnSeTe, CdZnSTe, CdHgSeS, CdHgSeTe, CdHgSTe, HgZnSeS, HgZnSeTe, HgZnSTe, and a combination thereof. The group III-V compound may be selected from: a group of two-element compounds selected from GaN, GaP, GaAs, GaSb, AlN, AlP, AlAs, AlSb, InN, InP, InAs, InSb, and a combination thereof; a group of three-element compounds selected from GaNP, GaNAs, GaNSb, GaPAs, GaPSb, AlNP, AINAs, AlNSb, AlPAs, AlPSb, InNP, InNAs, InNSb, InPAs, InPSb, GaAlNP, and a combination thereof; and a group of four-element compounds selected from GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a combination thereof. The group IV-VI compound may be selected from: a group of two-element compounds selected from SnS, SnSe, SnTe, PbS, PbSe, PbTe, and a combination thereof; a group of three-element compounds selected from SnSeS, SnSeTe, SnSTe, PbSeS, PbSeTe, PbSTe, SnPbS, SnPbSe, SnPbTe, and a combination thereof; and a group of four-element compounds selected from SnPbSSe, SnPbSeTe, SnPbSTe, and a combination thereof. The group IV element may be selected from a group of Si, Ge, and a combination thereof. The group IV compound may be a two-element compound selected from a group of SiC, SiGe, and a combination thereof.

In this case, the two-element compound, three-element compound, or four-element compound may be present in a particle in uniform concentrations or may have partially different concentrations in the same particle, respectively. In addition, a core/shell structure in which one quantum dot encloses anther quantum dot may be possible. An interfacing surface between the core and the shell may have a concentration gradient in which a concentration of an element decreases closer to its center.

The quantum dot may have a full width at half maximum (“FWHM”) of a light emission wavelength spectrum of about 45 nanometers (nm) or less, such as about 40 nm or less, and more particularly about 30 nm or less. In these ranges, color purity or color reproducibility can be improved. In addition, light emitted through such a quantum dot is omni-directionally emitted so that a wide viewing angle can be improved.

In addition, shapes of the quantum dot are not specifically limited to shapes that are generally used in the related art. In exemplary embodiments, a nanoparticle having a spherical, pyramidal, multi-arm, or cubic shape, a nanotube, a nanowire, a nanofiber, and a planar nanoparticle may be used.

When the first semiconductor nanocrystals 331R includes a red phosphor, the red phosphor may include one of (Ca, Sr, Ba)S, (Ca, Sr, Ba)₂Si₅N₈, CaAlSiN₃, CaMoO₄, and Eu₂Si₅N₈, but this is not restrictive.

When the second semiconductor nanocrystals 331G includes a green phosphor, the green phosphor may include at least one of yttrium aluminum garnet (YAG), (Ca, Sr, Ba)₂SiO₄, SrGa₂S₄, barium magnesium (BAM), alpha SiAlON (α-SiAlON), beta SiAlON (β-SiAlON), Ca₃Sc₂Si₃O₁₂, Tb₃Al₅O₁₂, BaSiO₄, CaAlSiON, and (Sr1-xBax)Si₂O₂N₂, but this is not restrictive. The x may denote any number between 0 and 1.

The transmission layer 330B may include a resin that transmits incident blue light. The transmission layer 330B corresponding to the area of the display device where the blue light is emitted does not include separate semiconductor nanocrystals, and thus incident blue light is directly transmitted without color or wavelength conversion thereof.

Although it is not illustrated in the present exemplary embodiment, the transmission layer 330B may include at least one of a pigment and a dye. The transmission layer 330B that includes a dye and a pigment may reduce reflection of external light and provide blue light having improved color purity.

The first color conversion layer 330R, the second color conversion layer 330G and the transmission layer 330B may each include, for example, a photosensitive resin.

In an exemplary embodiment of manufacturing a display device, the first color conversion layer 330R, the second color conversion layer 330G, and the transmission layer 330B may be manufactured through a photolithography process. Alternatively, the first color conversion layer 330R, the second color conversion layer 330G and the transmission layer 330B may be manufactured through a printing process or an inkjet process. In the case of the printing or inkjet processes, the first color conversion layer 330R, the second color conversion layer 330G and the transmission layer 330B may include a material other than the photosensitive resin. In this present exemplary embodiment, the color conversion layers (330R and 330G) and the transmission layer (330B) are manufactured through a photolithography process, a printing process or an inkjet process, but this is not restrictive.

At least one of the first color conversion layer 330R, the second color conversion layer 330G and the transmission layer 330B may further include a (light) scatterer 335. The scatterer 335 may be provided in plurality with such layers. In an exemplary embodiment, for example, the first color conversion layer 330R, the second color conversion layer 330G and the transmission layer 330B may respectively include the light scatterer 335, or the transmission layer 330B includes the scatterer 335 and the first and second color conversion layers 330R and 330G do not include the scatterer 335, or various other exemplary embodiments are possible. The amount of each scatterer 335 included in the first color conversion layer 330R, the second color conversion layer 330G and the transmission layer 330B may be different.

The scatterer 335 may include any material that can uniformly scatter incident light. The scatterer 335 may include at least one of TiO₂, ZrO₂, Al₂O₃, In₂O₃, ZnO, SnO₂, Sb₂O₃, and indium tin oxide (“ITO”). A light filter layer 340 may be disposed between each of the plurality of color conversion layers 330R and 330G and the upper panel 200, and between the transmission layer 330B and the upper panel 200. The light filter layer 340 may extend to overlap an entirety of the third substrate 310. In an exemplary embodiment, the light filter layer 340 may be omitted.

The light filter layer 340 may be a filter that transmits light of a specific wavelength and reflects or absorbs light of other than the specific wavelength. The light filter layer 340 may include a structure in which a layer having a relatively high refractive index and a layer having a relatively low refractive index are alternately laminated about 10 to 20 times in a thickness direction to form a multilayered structure. That is, the light filter layer 340 may have a structure in which a plurality of layers, each having a different refractive index, are laminated. Light having a specific wavelength can be transmitted and/or reflected by using reinforcement and/or destructive interference between the layer having the relatively high refractive index and the layer having the relatively low refractive index.

The light filter layer 340 may include at least one of TiO₂, SiNₓ, SiO_{y}, TiN, AlN, Al₂O₃, SnO₂, WO₃, and ZrO₂, and may have a structure in which SiNₓ and SiO_{y} are alternately laminated. In SiNₓ and SiO_{y}, x and y are factors that determine a chemical composition ratio, and may be adjusted according to conditions of a film forming process.

A portion of the light filter layer 340 may serve as a capping layer within the display device. In an exemplary embodiment of manufacturing a display device, a portion of the light filter layer 340 disposed on in the first color conversion layer 330R and the second color conversion layer 330G can reduce or effectively prevent damage to and light quenching of the semiconductor nanocrystals 331R and 331G included in the first color conversion layer 330R and the second color conversion layer 330G, that may occur during relatively high-temperature processes performed after forming the first color conversion 330R, the second color conversion layer 330G, and the transmission layer 330B.

An overcoat layer 350 is disposed between the light filter layer 340 and the liquid crystal layer 3. The overcoat layer 350 may extend to overlap an entirety of the third substrate 310. The overcoat layer 350 may planarize one side of each of the first color conversion layer 330R, the second color conversion layer 330G and the transmission layer 330B. The overcoat layer 350 may include an organic material, but this is not restrictive. The overcoat layer 350 may include any material that can serve a planarization function.

An adhesion layer 22A may be disposed between the overcoat layer 350 and the second polarization layer 22. The adhesion layer 22A may bond the overcoat layer 350 and the second polarization layer 22 to each other.

The display device according to the exemplary embodiment includes the first substrate 110, the second substrate 210 and the third substrate 310, each having flexibility and including a polymer so that the display device can be deformed or bent. Further, the first polarization layer 12 and the second polarization layer 22 are provided in the form of a film that is attached to one substrate by using an adhesion layer such that the display device can be deformed or bent.

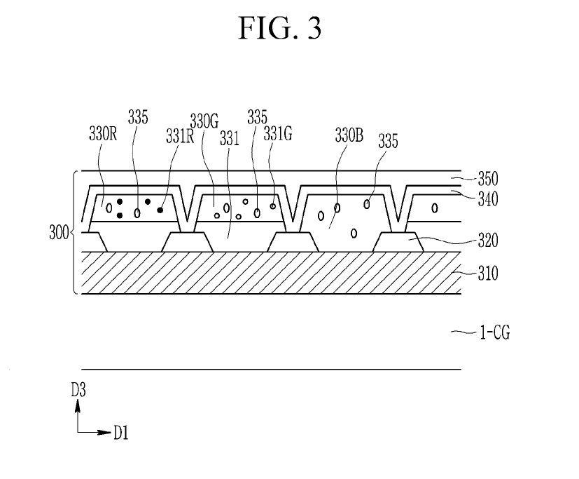

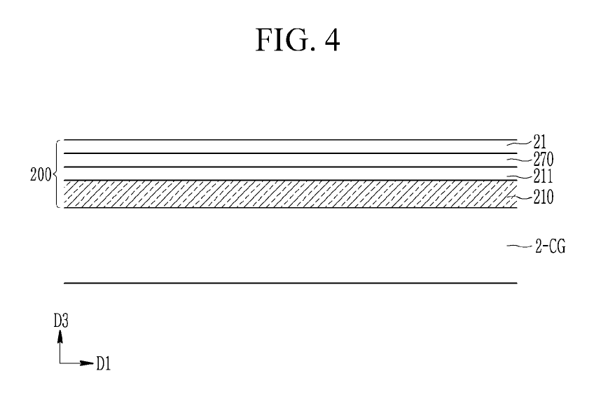

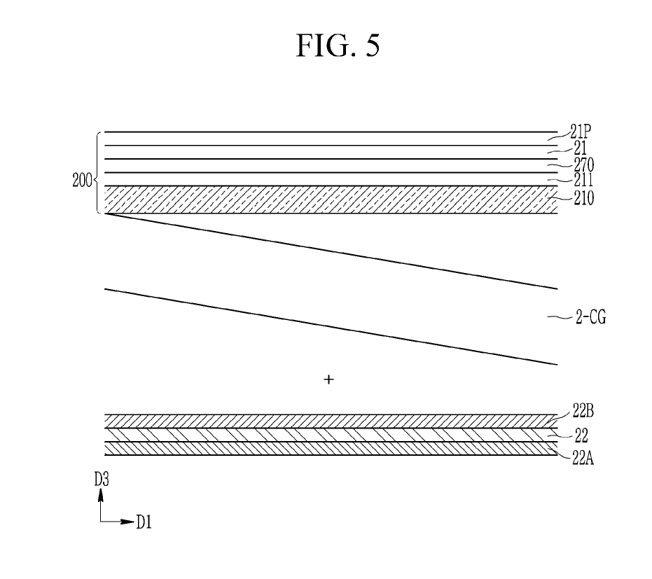

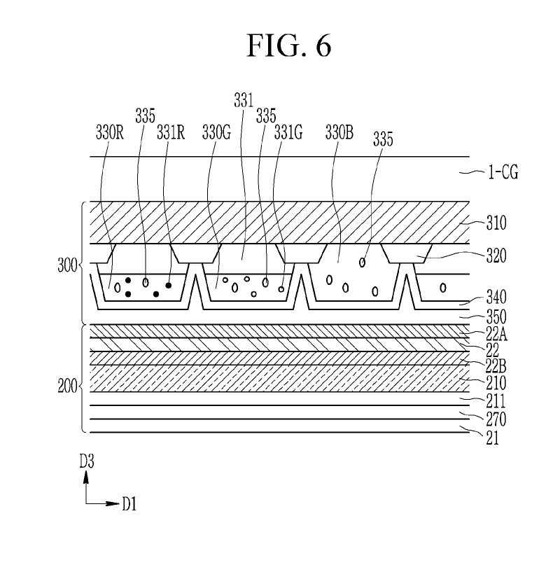

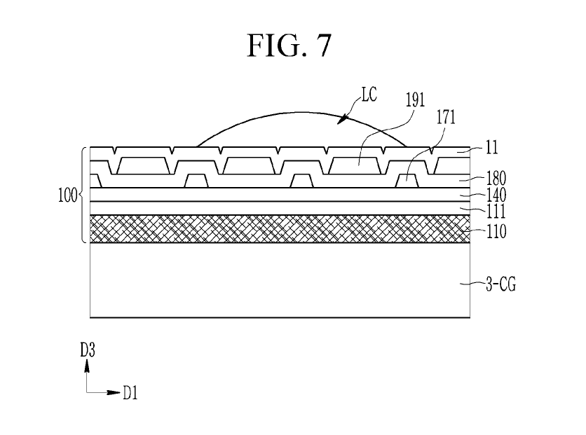

Hereinafter, an exemplary embodiment of a method for manufacturing a display device will be described with reference to FIG. 3 to FIG. 6. FIG. 3, FIG. 4, FIG. 5 and FIG. 6 are cross-sectional views illustrating exemplary embodiment of a manufacturing process of a display device according to the invention.

Referring to FIG. 3, in forming a color conversion display panel 300, a third substrate 310 including a polymer, a light blocking member 320, color conversion layers 330R and 330G, a transmission layer 330B, a light filter layer 340, and an overcoat layer 350 are sequentially laminated on a first carrier substrate 1-CG.

Although it is not illustrated in the drawings, a buffer layer may further be provided between the first carrier substrate 1-CG and the light blocking member 320.

As shown in FIG. 4, in forming a portion of an upper panel 200, a second substrate 210 is disposed on a second carrier substrate 2-CG, and a second buffer layer 211, a common electrode 270 and a second alignment layer 21 are sequentially laminated on the second substrate 210.

As shown in FIG. 5, a passivation film 21P is laminated on the second alignment layer 21 in the stacked laminated structure of the second buffer layer 211, the common electrode 270, the second alignment layer 21 and the second substrate 210. The passivation film 21P may help separation of the second carrier substrate 2-CG from remaining layers thereon while protecting the second alignment layer 21. The passivation film 21P may have an adhesion strength, for example, about 5 gf/in to about 10 gf/in, as compared to an adhesion strength of the second substrate 210 being about 1 gf/in. That is, as shown in FIG. 5, the passivation film 21P remains attached to layers of the upper panel 200 while the second substrate 210 is separated from the second carrier substrate 210.

Through a peel-off process, the second substrate 210 with the layers of the stacked structure thereon and the second carrier substrate 2-CG are separated from each other. The second substrate 210 and the second carrier substrate 2-CG according to the exemplary embodiment can be detached without performing a separate laser process. The second substrate 210 including a polymer and the second carrier substrate 2-CG including a glass material have a weak physical bonding force with respect to each other, and therefore they can be separated from each other by using solely air injection without performing a separate laser process.

In forming a complete upper panel 200, one surface of the second substrate 210, exposed by separation of the second carrier substrate 2-CG therefrom, may be bonded (shown by + in FIG. 5) with an adhesion layer 22B that is disposed on one surface of the second polarization layer 22. An opposite surface to the one surface of the second polarization layer 22 may be bonded with the color conversion display panel 300 manufactured in FIG. 3 through another adhesion layer 22A. A portion of the display panel including the completed upper display panel 200 and the completed color conversion display panel 300 bonded to each other can be manufactured as shown in FIG. 6. The first carrier substrate 1-CG remains on the color conversion display panel 300. The passivation film 21P shown in FIG. 5 may be removed to expose a surface of the second alignment layer 21 as shown in FIG. 6.

As shown in FIG. 7, in forming a lower panel 100, a first substrate 110, a first buffer layer 111, a thin film transistor, a gate insulation layer 140 that is disposed between a gate electrode of the thin film transistor and a semiconductor layer, a passivation layer 180 disposed on a source electrode and a drain electrode and a pixel electrode 191 are provided on a third carrier substrate 3-CG. A liquid crystal material LC is dripped on the stacked structure of the lower panel 100.

The upper panel 200 and the color conversion display panel 300 manufactured as shown in FIG. 6, and the lower panel 100 having the third carrier substrate 3-CG attached thereto as shown in FIG. 7, are bonded to each other.

In an exemplary embodiment, although not shown in the drawings, the lower panel 100 may be bonded to the upper panel 200 attached to the color conversion display panel 300, by a sealing member or the like in a sealing region of the display device. The liquid crystal material LC may be sealed between the upper and lower panels 200 and 100 by the sealing member.

With the lower panel 100 bonded to the upper panel 200 attached to the color conversion display panel 300, the first carrier substrate 1-CG remaining on the third substrate 310 as shown in FIG. 6, is removed to expose the third substrate 310.

Referring back to FIG. 2, the anti-reflection film 32 is attached to the exposed surface of the third substrate 310 from which first carrier substrate 1-CG is removed. In addition, the third carrier substrate 3-CG remaining on the first substrate 110 shown in FIG. 7 is removed to expose the first substrate 110. Referring again to FIG. 2, the first polarization layer 12 is attached to the exposed surface of the first substrate 110 from which the third carrier substrate 3-CG is removed, such that the display device shown in FIG. 2 can be provided.

In one or more exemplary embodiment, the substrates 110, 210 and 310 and the carrier substrates 1-CG, 2-CG and 3-CG according to the exemplary embodiment can be respectively detached from each other without performing an additional laser process.

The flexible substrates 110, 210 and 310 including a polymer and the carrier substrates 1-CG, 2-CG and 3-CG including a glass material have a weak physical bonding force relative to each other, and therefore they can be separated solely by using air injection without performing a separate laser process. Unlike a conventional display device in which a carrier substrate is separated from a base substrate by performing a laser process, defects due to laser and desorption processes can be reduced in exemplary embodiments according to the invention.

While this invention has been described in connection with what is presently considered to be practical example embodiments, it is to be understood that the invention is not limited to the disclosed embodiments, but, on the contrary, is intended to cover various modifications and equivalent arrangements included within the spirit and scope of the appended claims.

What is claimed is:

1. A display device comprising:
a lower panel through which incident light passes, the lower panel comprising a substrate on which a thin film transistor is disposed;
a color conversion display panel from which converted light is emitted to display an image, the color conversion display panel overlapping the lower panel; and
a polarization film disposed between the lower panel and the color conversion display panel,
wherein
the color conversion display panel comprises a substrate on which are disposed:
a first color conversion layer including first semiconductor nanocrystals which convert the incident light to the converted light;
a second color conversion layer including second semiconductor nanocrystals which convert the incident light to the converted light; and
a transmission layer through which unconverted incident light passes,
and
the substrate of the lower panel or the substrate of the color conversion display panel comprises a flexible substrate including a polymer.

2. The display device of claim 1, further comprising an upper panel through which the incident light passed through the lower panel passes to the color conversion display panel,
wherein with the substrate of the lower panel or the substrate of the color conversion display panel comprising the flexible substrate including the polymer, the upper panel comprises a flexible substrate including a polymer.

3. The display device of claim 2, wherein the polarization film is disposed between the upper panel and the color conversion display panel.

4. The display device of claim 2, further comprising an adhesion layer disposed between the polarization film and the upper panel and between the polarization film and the color conversion display panel.

5. The display device of claim 4, wherein the adhesion layer comprises at least one of a pressure sensitive adhesive, an optically clear adhesive and an optically clear resin.

6. The display device of claim 1, wherein the flexible substrate including the polymer comprises at least one of an acryl resin, a polycarbonate and a cycloolefin polymer.

7. The display device of claim 1, further comprising:
a light unit which generates blue light as the incident light and emits the incident blue light to the lower panel; and
a first polarization layer disposed between the lower panel and the light unit and into which the incident blue light is incident to the display device.

8. The display device of claim 2, wherein the substrate of the lower panel, the substrate of the color conversion display panel and the flexible substrate of the upper panel each has a thickness of about 1 micrometer to about 10 micrometers.

9. The display device of claim 8, further comprising an anti-reflection film disposed on the upper panel and through which the converted light exits the display device to display the image.

10. The display device of claim 1, wherein the display device is curved.

11. A display device comprising:
a lower panel through which incident passes, the lower panel comprising a thin film transistor;
a color conversion display panel from which converted light is emitted to display an image, the color conversion display panel overlapping the lower panel;
a light unit which generates blue light as the incident light and emits the incident blue light to the lower panel;
a first polarization layer disposed between the lower panel and the light unit;
a polarization film disposed on the color conversion display panel to face the lower panel; and
an adhesion layer disposed between the polarization film and the color conversion display panel,
wherein the color conversion display panel comprises:
a first color conversion layer including first semiconductor nanocrystals which convert the incident light to the converted light;
a second color conversion layer including second semiconductor nanocrystals which convert the incident light to the converted light; and
a transmission layer through which unconverted incident light passes.

12. The display device of claim 11, further comprising an upper display panel through which the incident light passed through the lower panel passes to the color conversion display panel,
wherein the upper panel comprises a flexible substrate including a polymer.

13. The display device of claim 12, wherein the polarization film is disposed between the color conversion display panel and the upper panel.

14. The display device of claim 12, further comprising an adhesion layer disposed between the polarization film and the upper panel.

15. The display device of claim 14, wherein the adhesion layer comprises at least one of a pressure sensitive adhesive, an optically clear adhesive and an optically clear resin.

16. The display device of claim 12, wherein the flexible substrate of the upper panel through which the incident light passed through the lower panel passes to the color conversion display panel, including the polymer, comprises at least one of an acryl resin, a polycarbonate and a cycloolefin polymer.

17. The display device of claim 12, wherein
the lower panel comprises a first substrate on which the thin film transistor is disposed,
the color conversion display panel comprises a second substrate on which are disposed the first color conversion layer, the second color conversion layer and the transmission layer, and
the flexible substrate of the upper panel, the first substrate of the lower panel and the second substrate of the color conversion display panel each has a thickness of about 1 micrometer to about 10 micrometer.

18. The display device of claim 17, further comprising an anti-reflection film disposed on the flexible substrate of the upper panel and through which the converted light exits the display device to display the image.

19. The display device of claim 11, wherein the display device is curved.
